(19) United States
(12) Patent Application Publication
(10) Pub. No.: US 2015/0104888 A1
(43) Pub. Date: Apr. 16, 2015

(54) SYSTEM FOR DETERMINING PRESENCE OF ABNORMALITY OF HEATER FOR SEMICONDUCTOR THIN FILM DEPOSITION APPARATUS

(71) Applicant: Do Hyeong LEE, Hwaseong-si (KR)

(72) Inventor: Do Hyeong LEE, Hwaseong-si (KR)

(21) Appl. No.: 14/511,492

(22) Filed: Oct. 10, 2014

(30) Foreign Application Priority Data
Oct. 13, 2013 (KR) 10-2013-0120543
Jan. 15, 2014 (KR) 10-2014-0005067

(51) Int. Cl. C23C 16/52; G01K 13/00; G01N 27/00; H01L 21/66; H01L 21/67

(52) U.S. Cl. CPC C23C 16/52; H01L 22/12; H01L 21/67253; G01N 27/00; G01K 13/00
USPC 438/14; 324/637

(57) ABSTRACT

The present invention relates, in general, to an apparatus for determining the presence of abnormality of a heater for a semiconductor thin film deposition apparatus, such as an aluminum or ceramic heater and, more particularly, to a technique for monitoring a phenomenon occurring in an apparatus during a semiconductor thin film deposition process and a phenomenon occurring in a heater, thereby determining the presence of abnormality of the heater. The present invention also relates to a technique for measuring, in real time, a thickness of a thin film deposited by driving of a heater during a thin film deposition process in a chamber, thereby determining the presence of abnormality of a wafer and the presence of abnormality of the heater, based on the measurement result.

### TECHNICAL FIELD

The present invention relates, in general, to an apparatus for determining the presence of abnormality of a heater for a semiconductor thin film deposition apparatus, such as an aluminum or ceramic heater and, more particularly, to a technique for monitoring a phenomenon occurring in an apparatus during a semiconductor thin film deposition process and a phenomenon occurring in a heater, thereby determining the presence of abnormality of the heater.

The present invention also relates to a technique for measuring, in real time, a thickness of a thin film deposited by driving of a heater during a thin film deposition process in a chamber, thereby determining the presence of abnormality of a wafer and the presence of abnormality of the heater, based on the measurement result.

### BACKGROUND OF THE INVENTION

As semiconductor devices are miniaturized, high productivity and high quality are required in semiconductor thin film processes. In the case of a chemical vapor deposition (CVD) apparatus that is a deposition apparatus for semiconductor, parameters having the greatest influence on reaction are source gas, temperature, RF power, pressure and the like. Particularly, the temperature is a core factor affecting resolution of the source gas in the thin film deposition apparatus, and a heater is mounted at a lower portion of a chamber to adjust the temperature.

In a deposition apparatus, RF voltages of 13.56 MHz and 370 kHz are applied from the top of a chamber. A heater system is mounted at a lower portion of the chamber to apply power to a heater (heat generation) coil connected to a chuck.

However, in the case of a heater performing this function, cracks are generated due to high stress of by-products accumulated on the heater or due to thermal stress caused by repetitive thermal stress. Accordingly, it is required to monitor damage that the heater may actually receive, using an RF filter.

As semiconductor devices are highly integrated, the device pitch size is gradually decreased and has reached 20 nm that is a physical limitation. Therefore, several plans for solving this problem are proposed.

These plans tend to change a conventional 2D type circuit design into a 3D type circuit design. A representative of the 3D type circuit design is to change conventional longitudinal circuit arrangement into lateral circuit arrangement, such as in a FIN-FET structure, a through silicon via (TSV) process and a vertical NAND flash memory. Particularly, in the case of the TSV process and the V-NAND flash memory, a test module line for full-scale mass production is configured, and thus its development accelerates.

However, in the case of a thin film deposition process used in the TSV process or the V-NAND flash memory, the time taken to perform the deposition process in a chamber is 20 to 60 minutes, which is a maximum of 40 times as compared with a conventional unit process.

If deposition is completed in conventional thin film equipments, a wafer is transferred to a thickness measuring device to measure the thickness of the wafer using a sampling method. Then, the measured data is transmitted to an SPC monitoring system to determine the presence of abnormality of the wafer and the presence of abnormality of a heater causing the abnormality of the wafer. However, since the range of measurement errors is large, and the measuring device is high-priced, it is unsuitable for field application.

As a means for solving this problem, there is known an apparatus for measuring thickness of thin film in Korean Patent No. 1206744 (registered on Nov. 26, 2012), which has high accuracy and inexpensive manufacturing cost.

However, in the case of a thin film deposition process used in a V-NAND flash memory, oxide/nitride films are alternately deposited, thereby depositing 16, 28 and 36 layers in one chamber, based on a pair of oxide/nitride films. When the entire thicknesses of the thin films are measured using a conventional ellipsometry in the chamber, there occurs a case where although the thickness of one layer is low but the thickness of another layer is high, the entire thicknesses of the thin films are equal. In this case, it is decided that the thin film deposition process has been normally performed, and as a result, there is a problem in that inferior products are frequently produced.

In conclusion, this problem is mainly caused by a semiconductor manufacturing apparatus, more specifically the presence of abnormality of a heater. Therefore, the preparation for the presence of abnormality of the heater is urgent.

### SUMMARY OF THE INVENTION

Accordingly, the present invention has been made keeping in mind the above problems occurring in the prior art, and an object of the present invention is to provide a heater monitoring system capable of determining the presence of abnormality of a heater, using an RF voltage supplied from the top of a chamber, in a heater system used in a deposition apparatus for semiconductor.

Another object of the present invention is to provide a system and a method for measuring a thickness of a thin film, which can determine the presence of abnormality of a wafer and the presence of abnormality of a heater causing the abnormality of the wafer by measuring, in real time, a thickness of a thin film in a semiconductor thin film deposition process of depositing the thin film for a long period of time.

In accordance with an aspect of the present invention, there is provided a heater monitoring system for a semiconductor thin film deposition apparatus, the heater monitoring system, including: an RF filter configured to detect that an RF signal applied from an RF supply unit is supplied to a heat generating coil of a heater in a plasma process, wherein the heater is made of any one of Al, AlN and BN, and the RF filter is disposed between a heater power rod and a power supply unit; a power supply unit configured to apply a driving voltage to the heater through the RF filter; and a diagnosis unit configured to diagnose the presence of abnormality of the heater by processing the RF signal transmitted from the RF supply unit.

The RF filter may include an RF signal blocking filter configured to block the supply of the RF signal from the RF supply unit to the power supply unit so that a rating voltage is supplied from the power supply unit to the heater; and a band pass filter connected to the diagnosis unit to pass band signals of the RF signal supplied to the heat generating coil of the heater and then transmit the band signals to the diagnosis unit.

The diagnosis unit may include a signal processing unit in the form of a comparator, configured to perform an operation of comparing the RF signal passing through a band pass filter with a normal signal or comparing accumulated error data with a set error allowance range; a determination unit configured to determine the presence of abnormality of the heater by receiving a signal of the signal processing unit; and an alarm unit configured to notify an abnormality of the heater to the exterior through an audible or visual means when the abnormality occurs in the heater as the determination result of the determination unit.

In accordance with another aspect of the present invention, there is provided a heater monitoring system for a semiconductor thin film deposition apparatus, the heater monitoring system including: an induced current sensor unit configured to sense that an induced current generated by an RF signal applied from the RF supply unit is supplied to a heat generating coil of a heater in a plasma process, wherein the heater is made of any one of Al, AlN and BN; a power supply unit configured to apply a driving voltage to the heater through the RF filter; and a diagnosis unit configured to include a signal processing unit in the form of a comparator, configured to compare a real-time signal sensed by the induced current sensor unit with a normal signal to diagnose the presence of abnormality of the heater by processing an induced current sensing signal transmitted from the induced current sensor unit, a determination unit configured to determine the presence of abnormality of the heater by receiving a signal of the signal processing unit, and an alarm unit configured to notify an abnormality of the heater to the exterior through an audible or visual means when the abnormality occurs in the heater as the determination result of the determination unit.

In accordance with yet another aspect of the present invention, there is provided a thin film measuring system, including: a chamber configured to accommodate a wafer having a thin film deposited thereon; an RF supply unit configured to supply an RF signal into the chamber; a heater configured to heat the wafer in the chamber, the heater receiving and outputting RF signals supplied from the RF supply unit; and a monitoring unit configured to calculate a difference between positive and negative values by detecting, in real time, the RF signal received in the heater in a thin film deposition process, measure a thickness of the thin film by comparing a calculated RF measurement value with an RF measurement value set for each thickness, and determine the presence of abnormality of the wafer and the presence of abnormality of the heater.

The thin film measuring system may further include an input signal detector configured to detect an RF signal supplied from the RF supply unit to the chamber and apply the detected RF signal to the monitoring unit; and an output signal detector configured to detect an RF signal output from the heater and apply the detected RF signal to the monitoring unit.

When an abnormality occurs in the RF measurement value, the monitoring unit may calculate a phase value from the RF signal received in the heater, and compare the calculated phase value with a phase value set for each thickness, thereby determining the presence of abnormality of the deposited thin film.

When an abnormality occurs in the RF measurement value, the monitoring unit may calculate a gain value from the RF signal received in the heater, and compare the calculated gain value with a gain value set for each thickness, thereby determining the presence of abnormality of the deposited thin film.

In accordance with further yet another aspect of the present invention, there is provided a thin film measuring method, including: an RF transmission/reception step of supplying an RF signal into a chamber, and receiving the RF signal in a heater on which a wafer mounted in the chamber; a thin film deposition step of depositing a thin film on the wafer through a reaction between gas and the RF signal supplied into the chamber in the RF transmission/reception step; an RF measurement value determining step of calculating an RF measurement value by operating a difference between positive and negative peak values in the RF signal supplied in the thin film deposition step, and comparing the calculated RF measurement value with an RF measurement value set for each thickness; and a warning step of warning an abnormality of the thickness of the thin film when the calculated RF measurement value is different from the set RF measurement value in the RF measurement value determining step.

The thin film measuring method may further include a phase detection step of detecting a phase of the RF signal when the calculated RF measurement value is different from the set RF measurement value in the RF measurement value determining step; and a phase value change determining step of determining whether the measured phase value is different from a phase value set for each thickness in the phase detection step. When it is determined that the measured phase value is different from the set phase value in the phase value change determining step, a warning may be given in the warning step.

The thin film measuring method may further include a gain value determining step of detecting a gain of the RF signal and determining whether the detected gain value is different from a set gain value, when the calculated RF measurement value is different from the set RF measurement value in the RF measurement value determining step. When the set gain value is different from the measured gain value in the gain value determining step, a warning may be given in the warning step.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a configuration diagram of a heater monitoring system for a semiconductor thin film deposition apparatus in accordance with an embodiment of the present invention, in which FIG. 1A is a configuration diagram of the heater monitoring system, FIG. 1B is a configuration diagram illustrating an RF supply unit connected to the top of a chamber and between a heater and an RF signal blocking filter, FIG. 1C is a configuration diagram illustrating the RF supply unit connected to the top of the chamber and a plate (flat board) line, and FIG. 1D is a diagram illustrating a diagnosis configured with a computer;

FIG. 2 is a configuration diagram of an RF filter of FIG. 1, which illustrates a noise removal filter and a band pass filter are configured as the RF filter;

FIG. 3 is a configuration diagram a diagnosis unit of FIG. 1;

FIG. 4 is a flowchart illustrating an operation of the heater monitoring system for the semiconductor thin film deposition apparatus in accordance with the embodiment of the present invention;

FIG. 5 is a configuration diagram a heater monitoring system for a semiconductor thin film deposition apparatus in accordance with another embodiment of the present invention, in which FIG. 5A is a configuration diagram of a heater monitoring system with respect to an aluminum heater, and FIG. 5B is a configuration diagram of a heater monitoring system with respect to a ceramic heater;

FIG. 6 is a diagram illustrating a sensor unit on a ground line using an induced electromotive force, configured in FIG. 5 in accordance with the embodiment of the present invention;

FIG. 7 is a configuration diagram illustrating a connection between an induced current sensor unit and a diagnosis unit in accordance with the embodiment of the present invention;

FIG. 8 is a block diagram of a thin film measuring system as a system for determining the presence of abnormality of a heater in accordance with yet another embodiment of the present invention;

FIG. 9 is a flowchart illustrating a thin film measuring operation using the system of FIG. 8;

FIG. 10 is a graph illustrating an RF reception signal of the thin film measuring system of FIG. 8;

FIG. 11 is a graph illustrating phases of output signals of the thin film measuring system of FIG. 8; and

FIG. 12 is a graph illustrating gains of output signals of the thin film measuring system of FIG. 8.

### DESCRIPTION OF THE PREFERRED EMBODIMENTS

Hereinafter, embodiments of the present invention will be described in detail with reference to the accompanying drawings. Reference now should be made to the elements of drawings, in which the same reference numerals are used throughout the different drawings to designate the same elements. In the following description, detailed descriptions of known elements or functions that may unnecessarily make the gist of the present invention obscure will be omitted.

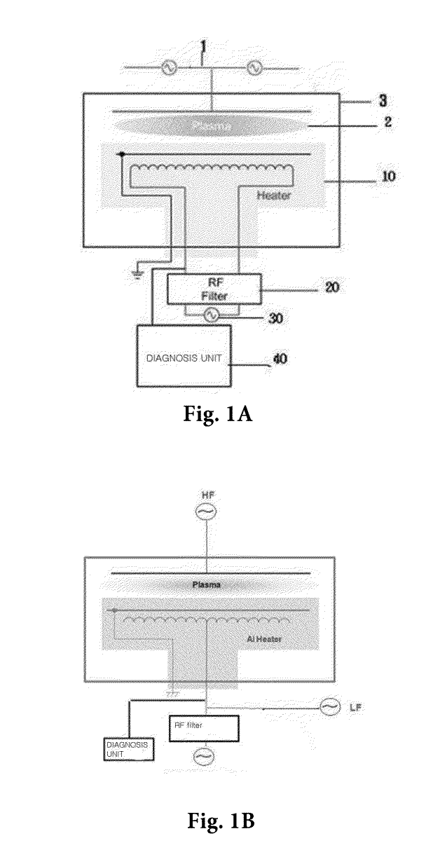

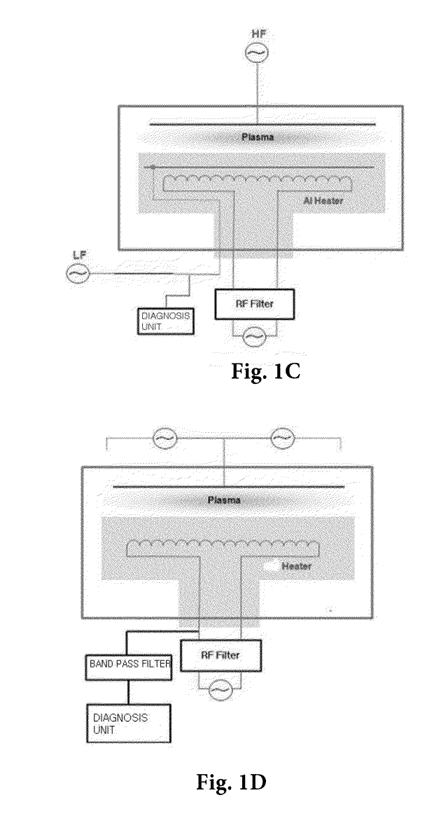

As shown in FIG. 1A, a heater monitoring system of the present invention includes a main body (omitting reference numeral) made of an aluminum ceramic material, and an RF filter 20 and a diagnosis unit 40, configured to diagnose the presence of abnormality of a heater 10 using an RF signal from an RF supply unit 1, applied in a plasma process, in a state in which the heater 10 configured with a heater coil is disposed in a process chamber 3.

The heater 10, as shown in FIG. 1, is driven to maintain a constant process temperature while a process is being performed, and a heat generating coil is inserted in a chuck on which a wafer is loaded. Thus, while a thin film deposition process is being performed, the plasma process is performed using the RF signal supplied from the RF supply unit 1 positioned above the heater 10, and a rating voltage is supplied from a power supply unit 30 positioned below the heater 10.

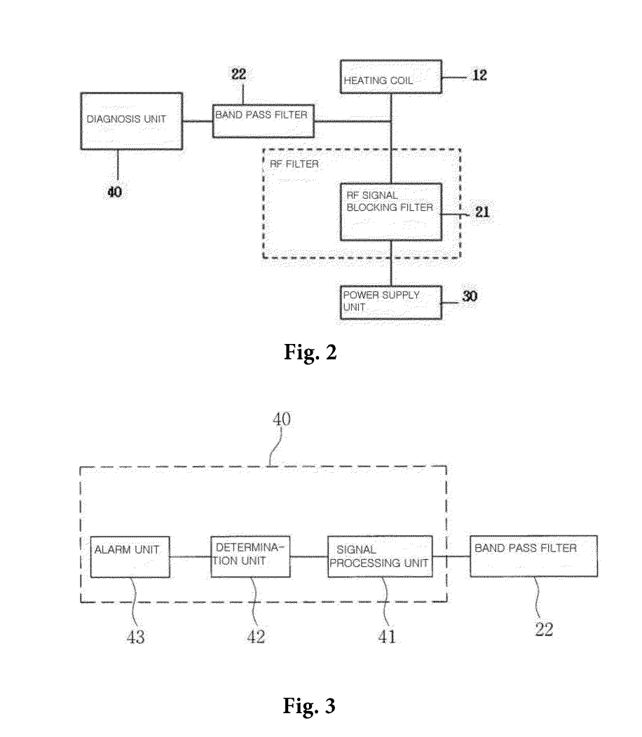

The RF filter 20, as shown in FIG. 2, is configured to perform a function for ensuring the stability of an actual driving voltage of the heater and a signal extraction function for diagnosing the presence of abnormality of the heater. The RF filter 20 detects that the RF signal applied from the RF supply unit 1 in the plasma process is provided to the heat generating coil of the heater 10, regardless of an aluminum heater or a ceramic heater.

Here, the RF signal may be a high-frequency signal or a low-frequency signal. The RF filter 20 is structurally positioned between the power supply unit 30 and a power rod of the heater 10.

The RF filter 20, as shown in FIG. 1A, is connected between the heat generating coil of the heater 10 and the power supply unit 30 so that power can be stably supplied from the power supply unit 30 to the heater 10. That is, the RF filter 20 enables the power to be stably supplied from the power supply unit 30 to the heater 10 by removing power signals that may be generated in the heat generating coil by the RF signal, and prevents a breakdown of the power supply unit 30 by preventing the RF signal from being supplied back to the power supply unit 30.

As such, the RF filter 20 is disposed between the heat generating coil of the heater 10 and the power supply unit 30 in order to perform a function for preventing a breakdown of the power supply unit 30 and a function for removing power signals that may be generated in the heat generating coil of the heater 10 so that the power is stably supplied to the heater 10. If the RF signal generated from the RF supply unit 1 is directly supplied to the power supply unit 30, the power supply 30 may be seriously damaged, and therefore, an RF signal blocking filter 21 included in the RF filter 20 prevents the RF signal from being supplied to the power supply unit 30.

A heater monitoring system shown in FIG. 1B has a configuration in which the RF filter shown in FIG. 1A does not exist. Unlike FIGS. 1A and 1B, a heater monitoring system shown in FIG. 1C has a configuration in which RF supply units are respectively connected to the top and bottom of the chamber.

In FIGS. 1A, 1B and 1C, the RF filter may be selectively included or excluded.

FIG. 1D illustrates a heater monitoring system in which the diagnosis unit is configured with a computer. Unlike FIGS. 1A, 1B and 1C, a band pass filter is directly connected from the heater, so that a signal passing through the band pass filter is processed by the diagnosis unit configured with the computer.

In FIGS. 1B to 1D, the reference numeral of each component is omitted.

As shown in FIG. 2, the RF filter 20 includes an RF signal blocking filter 21 connected between the heat generating coil of the heater 10 and the power supply unit 30 to block the RF signal from being supplied to the power supply unit 30, and a band pass filter 22 connected to the diagnosis unit 40 to pass predetermined band signals of an RF signal supplied to the heater 10 and a ground line through a transmission line from that through which the RF signals are supplied to the RF signal blocking filter 21.

The diagnosis unit 40, as shown in FIG. 2, determines the presence of abnormality of the heater 10, based on RF signals passing through the band pass filter 22 of the RF filter 20, and allows a stable voltage having the RF signals removed therefrom to be supplied from the power supply unit 30, based on the determination result.

The diagnosis unit 40, as shown in FIG. 3, is configured with a module for performing signal processing, and may be implemented with hardware or software. The diagnosis unit 40 includes a signal processing unit 41 in the form of a comparator for comparing an RF signal (hereinafter, referred to as a real-time signal) passing through the band pass filter 22 with a normal signal, a determination unit 42 for determining the presence of abnormality of the heater 10 by receiving a signal of the signal processing unit 41, and an alarm unit 43 for notifying an abnormality of the heater 10 to the exterior through an audible or visual means when the abnormality of the heater 10 occurs as the determination result of the determination unit 42.

Meanwhile, the diagnosis unit 40, as shown in FIG. 1A, may be configured to receive RF signals containing noises before RF signals are supplied to the RF filter 20. When the diagnosis unit 40 is configured as described above, the diagnosis unit 40 should diagnose the RF signals containing the noises. Therefore, a diagnosis reference value should be changed to prepare for when the abnormality of the heater is determined based on signals from which the noises included in the RF signals are removed. When the diagnosis is made based on signals containing noises, a more precise diagnosis reference is required.

Instead of comparing the real-time signal with the normal signal, the signal processing unit 41 receives error data input from the band pass filter 22 of the RF filter 20 and accumulates the error data. The determination unit 42 processes the error data to compare the accumulated error data with a set error allowance range.

The real-time signal (RF signal) used in the diagnosis unit 40 may use an original signal transmitted from the band pass filter 22 of the RF filter 20 as it is, or use a signal modulated in a form where the diagnosis is easily made through separate signal processing. The RF filter 20 and the diagnosis unit 40 may be directly connected to each other, or be connected by a coupling method for having no influence on a load of a heater system.

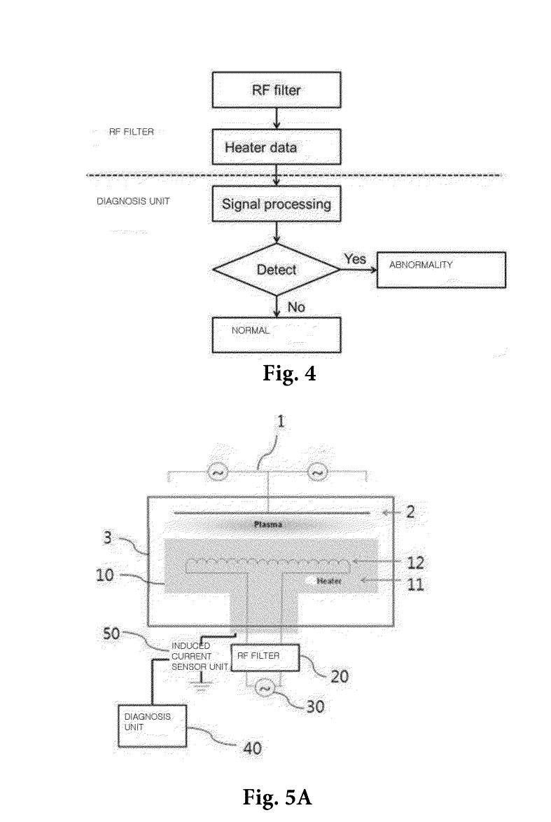

FIG. 4 is a flowchart illustrating an operation of the heater monitoring system.

As shown in FIG. 4, the real-time signal (RF signal) supplied to the heat generating coil of the heater 10 through the plasma process passes through the band pass filter 22 of the RF filter 20 and is transmitted to the signal processing unit 41 of the diagnosis unit 40.

The signal processing unit 41 processes a real-time signal transmitted from the RF filter 20 to be easily determined by the determination unit 42 that is a comparator, and the determination unit 42 compares the real-time signal processed by the signal processing unit 41 with the normal signal. The comparison operation may be replaced by an operation of comparing the accumulated error data with the error data in the set error allowance range.

If the real-time signal is within the range of the normal signal as the comparison result of the determination unit 42, the determination unit 42 determines that the heater 10 is normally driven. If the real-time signal is not within the range of the normal signal, the determination unit 10 determines that an abnormality has occurred in the heater 10.

Thus, an alarm is generated from the alarm unit 43, so that a manager can recognize the alarm.

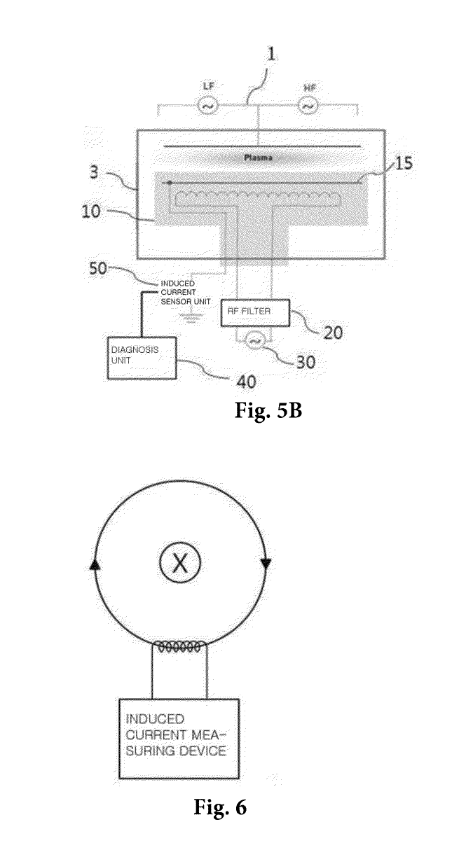

FIG. 5 illustrates a heater monitoring system in accordance with another embodiment of the present invention. When the presence of abnormality of the heater 10 is monitored by the diagnosis unit 40 using an RF signal transmitted from the RF filter 20, there may occur a phenomenon that the impedance of the heater 10 increases. The embodiment of the present invention provides a technique for preventing the phenomenon.

The heater monitoring system in accordance with the embodiment of the present invention includes an induced current sensor unit 50 to use an induced current detected from the ground. The induced current may be an induced voltage.

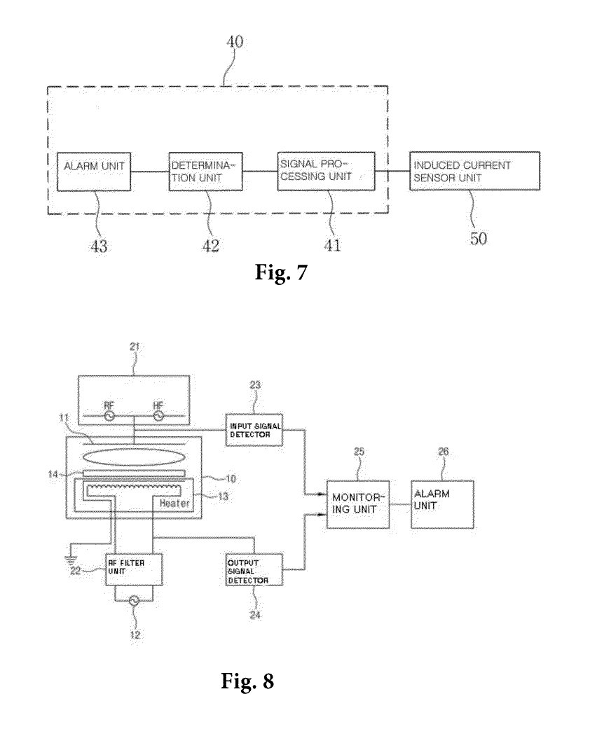

In the heater monitoring system in accordance with the embodiment of the present invention, configured as described above, the diagnosis unit 40 is configured as shown in FIG. 7, and the monitoring of the heater 10 is possible through the configuration of a diagnosis system including a signal processing unit 41 in the form of a comparator for comparing a real-time signal detected by the induced current sensor unit 50 with a normal signal, a determination unit 42 for determining the presence of abnormality of the heater 10 by receiving a signal of the signal processing unit 41, and an alarm unit 43 for warning an abnormality of the heater 10 or notifying the abnormality of the heater 10 to the exterior through a visual means when the abnormality of the heater 10 occurs as the determination result of the determination unit 42.

The heater monitoring operation will be described using the diagnosis system. If current induced from a voltage applied to the heater 10 is detected by the induced current sensor unit 50, the detected signal is transmitted to the signal processing unit 41 of the diagnosis unit 40.

The signal processing unit 41 processes a real-time signal transmitted from the induced current sensor unit 50 to be easily determined by the determination unit 42 that is a comparator, and the determination unit 42 compares the real-time signals processed by the signal processing unit 41 with the normal signal.

If the real-time signal is within the range of the normal signal as the comparison result of the determination unit 42, the determination unit 42 determines that the heater 10 is normally driven. If the real-time signal is not within the range of the normal signal, the determination unit 10 determines that an abnormality has occurred in the heater 10.

Thus, an alarm is generated from the alarm unit 43, so that a manager can recognize the alarm.

FIG. 6 is a diagram illustrating an induced current measuring device used in FIG. 5. The induced current measuring device is a non-contact type system capable of measuring a current signal without applying a load to the device.

FIG. 8 is a block diagram of a thin film measuring system for determining the presence of abnormality of a heater in accordance with yet another embodiment of the present invention.

In FIG. 8, components identical to those of the aforementioned embodiments are designated by like reference numerals.

Referring to FIG. 8, the thin film measuring system in accordance with the embodiment of the present invention includes a chamber 13, an RF supply unit 21 for transmitting an RF signal, an RF filter unit 22 for removing noise of the RF signal received in the chamber 13, an input signal detector 23 for detecting an RF input signal transmitted to the chamber 3, an output signal detector 24 for detecting an RF output signal output from the chamber 13, a monitoring unit 25 for calculating an RF average value from the RF output signal and comparing the calculated RF average value with an RF average value set for each thickness of thin films, thereby determining the presence of abnormality of the thickness, and an alarm unit 26 for warning an abnormality of the thickness of the thin film under the control of the monitoring unit 25. When it is determined that an abnormality has occurred in the thickness of the thin film, the abnormality may be set to be determined as an abnormality of a heater 10.

In the thin film measuring system configured as described above, the RF supply unit 21, the chamber 13, the RF filter unit 22 and the like are the same components as the aforementioned embodiments. The monitoring unit 25 performs a function identical or similar to that of the diagnosis unit 40 of the aforementioned embodiments, and the alarm unit 26 performs a function identical or similar to that of the alarm unit 43 of the aforementioned embodiments.

As can be seen in the configuration described above, the thin film measuring system in accordance with the embodiment of the present invention also uses RF signals. In the aforementioned embodiments, an RF signal supplied from the RF supply unit 1 is directly received in the heater to be input to the RF filter 20. On the other hand, in the embodiment of the present invention, the RF signal is a signal obtained by detecting a signal passing through a thin film laminated on a wafer 14 disposed on the top of the heater 10.

The RF supply unit 21 supplies an RF signal to the interior of the chamber 13. Here, the RF supply unit 21 preferably includes a high band filter and a low band filter in order to supply a signal having a frequency within a set range.

The chamber 13 includes the heater for heating the wafer 14, and a shower head 11 for spraying gas, and the heater 10 is driven by power supplied from a power supply unit 12.

The shower head 11 sprays an injected gas into the chamber 13, and the gas generates a plasma phenomenon through its electrical coupling with the RF signal in the chamber 13, thereby sequentially forming one or more thin film layers on the top surface of the wafer 14.

The heater 10 is connected to a ground terminal and the power supply unit 12, and heats the wafer 14 mounted thereon. Here, the heater 10 is provided with a heat coil for allowing heat to be generated by power applied from the power supply unit 12, and thus can act as an antenna for receiving the RF signal supplied from the RF supply unit 21. Accordingly, the heater 10 receives the RF signal supplied from the RF supply unit 21 and outputs the received RF signal to the RF filter unit 22.

Here, the RF signal is received in the heater 10 by passing through a thin film laminated on the top surface of the wafer by the plasma phenomenon through a reaction between the RF signal and the gas supplied from the shower head 11. Thus, the thin film acts as a dielectric. Accordingly, the RF signal output from the heater 10 has a certain RF measurement value depending on a thickness of the thin film.

The measurement value of the RF signal is a difference between positive and negative peak values of the RF signal received in the heater 10. The measurement value of the RF signal is changed depending on a thickness of the thin film.

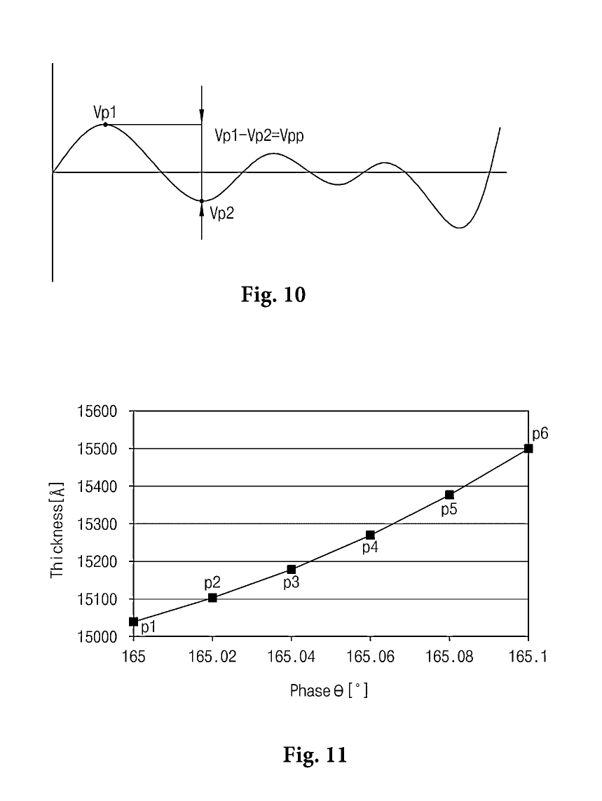

Referring to FIG. 10, the RF signal received in the heater 10 has peak values (Vp1 and Vp2) respectively in positive and negative sections. As thickness of the thin film increases, the RF measurement value (Vp1−Vp2=Vpp) that is a difference between peak values is changed. That is, the measurement value of the receive RF signal has a value within a certain range depending on a thickness of the thin film.

Thus, in the present invention, the presence of abnormality of the thickness of the thin film can be determined by setting an RF measurement value for each thickness of thin films and comparing the set RF measurement value with a measured RF measurement value.

The RF filter unit 22 is connected to both ends of the heater 10 to remove noise of the RF signal received in the heater 10.

The input signal detector 23 detects current and voltage, output from the RF supply unit 21, and applies the detected current and voltage to the monitoring unit 25.

The output signal detector 24 detects an RF signal received at both the ends of the heater 10 and applies the detected RF signal to the monitoring unit 25.

The monitoring unit 25 controls the RF supply unit 21 to supply an RF signal. Subsequently, the monitoring unit 25 calculates an RF measurement value by receiving the RF signal received in the heater 10 from the output signal detector 24, and determines whether the thickness of a thin film deposited on the wafer 14 is different from the set thickness by comparing the calculated RF measurement value with the set RF measurement value.

As one layer is further deposited on the thin film, the entire thickness of the thin film increases, so that the electrical resistance of the thin film increases. Thus, as the thickness of the thin film increases, the resistance of the RF signal received in the heater 10 acting as an antenna increases, so that a change in peak value occurs. However, the difference (RF measurement value) between positive and negative peak values is shown constant for each thickness.

Thus, the monitoring unit 25 can identify, in real time, the presence of abnormality of the thickness of the thin film by calculating, in real time, an RF measurement value set for each thickness of thin films and positive and negative peak values calculated in the RF signal received in the output signal detector 24, and comparing the set RF measurement value with an RF measurement value calculated as an average value of differences between the calculated peak values.

In addition, the monitoring unit 25 finally determines the presence of abnormality by identifying the phase and/or gain of an input signal of the RF signal and the phase and/or gain of an output signal of the RF signal in order to increase the accuracy of the thickness measurement result using the RF signal.

To this end, the monitoring unit 25 sets and stores, for each thickness, a phase and a gain according to the intensity of voltage or current. Thus, the monitoring unit 25 determines the presence of abnormality by comparing the phase and/or gain set for each thickness of the entire thin film whenever one layer is deposited on the thin film with the phase and/or gain detected from each of the input signal detector 23 and the output signal detector 24, and measuring the thickness of the thin film.

Next, a thin film measuring method in accordance with the present invention will be described with reference to the accompanying drawings.

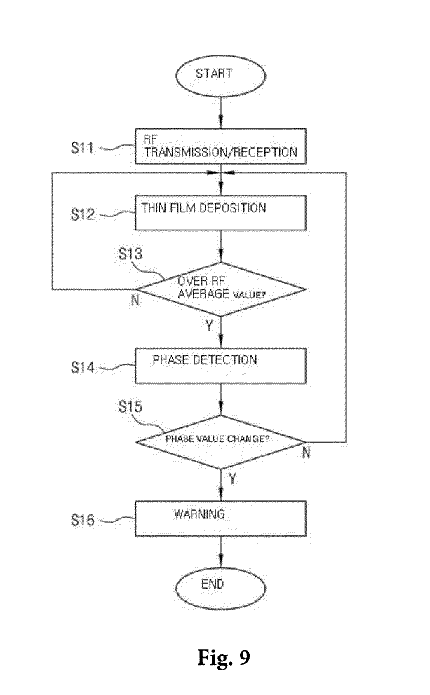

FIG. 9 is a flowchart illustrating a thin film measuring method in accordance with the present invention.

Referring to FIG. 9, the thin film measuring method in accordance with the present invention includes an RF transmission/reception step (S11) of transmitting and receiving RF signals in the chamber 13, a thin film deposition step (S12) of depositing a thin film by supplying gas into the chamber 13, an RF average value determining step (S13) of comparing an RF average value of RF signals output from the chamber 13 with a set RF average value, a phase detection step (S14) of detecting a phase when the RF average value of the RF signals received in the RF average value determining step (S13) is different from the set RF average value, a phase value change determining step (S15) of determining whether the phase value set in the phase detection step (S14) is different from a measured phase value, and a warning step (S16) of warning that an abnormality occurs in the thickness of the deposited thin film when it is determined that the set phase value is different from the measured phase value in the phase value change determining step (S15).

The RF transmission/reception step (S11) is a step of receiving an RF signal in the heater 10 when the RF signal is supplied to the chamber 13 by controlling the RF supply unit 21 in the monitoring unit 25. The RF supply unit 21 has a low band filter and a high band filter to transmit an RF signal having a frequency in a set range.

The shower head 11 acts as a transmission antenna of the RF supply unit 21, and the heater 10 acts as a reception antenna, so that the RF signal supplied from the RF supply unit 21 is received and output.

The thin film deposition step (S12) is step of depositing a thin film on the wafer 14 using plasma generated through electrical and chemical coupling between gas and the RF signal supplied into the chamber 13 as the wafer 14 is mounted on the top of the heater 10, and the gas is supplied through the shower head 11. Here, as power is applied to the heater, the heater 10 heats the wafer 14 mounted on the top thereof.

The RF average value determining step (S13) is a step of comparing an RF average value calculated by operating a difference between positive and negative peak values of an RF signal detected through each of the input signal detector 23 and the output signal detector 24 with a set RF average value for each thickness of thin films in the monitoring unit 25.

Here, the RF signal detected in each of the input signal detector 23 and the output signal detector 24 is received as a sine wave, and the RF average value is gradually decreased according to the number of layers of the thin film and the thickness of the entire thin film. For example, when a first layer of the thin film is deposited on the top of the wafer 14, the difference between the RF signal and the peak value becomes Vₚₚ₁. When a second layer of the thin film is deposited, the difference between the RF signal and the peak value becomes Vₚₚ₂. When a third layer of the thin film is deposited, the difference between the RF signal and the peak value becomes Vₚₚ₃. Thus, the monitoring unit 25 measures the thickness of the deposited thin film by calculating an average value of the differences between the RF signal and the peak values of the first to third layers and comparing the calculated average value with the set RF average value, so that it is possible to determine the presence of abnormality of the thickness of the thin film.

That is, the monitoring unit 25 sets an RF average value of RF signals changed as the thickness of the thin film increases for each thickness (each layer) of the thin film, and comparing the RF average value of RF signals received whenever the thickness of the thin film increases with the set RF average value, thereby determining the presence of the abnormality.

The phase detection step (S14) is a step of identifying the phase of the input/output RF signal when it is determined that the RF average value measured by the monitoring unit 25 is different from the set RF average value in the RF average value determining step (S13).

Here, both ends of the wafer 14 may be lifted by heat generation of the heater 10. In this case, the reception distance of the RF signal may be lengthened as both the ends of the wafer 14 are lifted. Therefore, although the thickness of the thin film for each layer is constant, the received RF signal may be influenced. This is well known by those skilled in the art.

Thus, in the present invention, the phase detection step (S14) is performed to compensate for the reception distance of the RF signal as the shape of the wafer 14 is changed during a process of measuring the thickness of the thickness using the RF signal.

That is, the thin film measuring system of the present invention has the input signal detector 23 and the output signal detector 24, configured as voltage or current sensors, to detect an RF signal supplied from the RF supply unit 21 and an RF signal received in the heater 10 and to compare a phase value calculated from the detected RF signals with a set phase value.

In the phase value change determining step (S15), the monitoring unit 25 detects the phase of an RF input signal supplied from the RF supply unit 21 to the chamber 13 and the phase of an RF output signal received in the heater 10, and compares the detected phase value with a set phase value. An example of the set phase value will be illustrated through a graph of FIG. 11.

FIG. 11 is a graph illustrating phase values in the thin film measuring system and the thin film measuring method in accordance with the present invention.

The graph of FIG. 11 illustrates phase values P₁ to P₆ measured according to the entire thickness of a thin film, increased as first to sixth layers of the thin film are sequentially deposited. Here, the phase value measured as the first layer is deposited represents P₁, and the phase value measured as the second layer is deposited represents P₂. As such, in the present invention, it can be seen in real time whether the thickness of a currently deposited thin film is lower or higher than a set thickness by setting a phase value according to the thickness of the entire thin film and comparing the phase value of the received RF signal with the set phase value.

Here, each of the input and output signals is, for example, Vₘsinwt or Iₘsinwt. Thus, the monitoring unit 25 detects a phase through an RF signal detected in each of the input signal detector 23 and the output signal detector 24, configured as a current or voltage sensor.

Accordingly, the monitoring unit 25 calculates a phase value from voltage or current detected through each of the input signal detector 23 and the output signal detector 24, particularly, an RF signal detected in the output signal detector 24, and compares the calculated phase value with the set phase value, thereby determining the presence of abnormality.

That is, if the calculated RF average value is different from the set RF average value, the monitoring unit 25 can identify the presence of error of the RF average value according to a change in the shape of the wafer 14 through the comparison of phase values.

The warning step (S17) is a step of warning that the thickness of a thin film currently deposited in the chamber 13 under the control of the monitoring unit 25 in the alarm unit 26 when the measured phase value is different from the set phase value in the monitoring unit 25. That is, in the present invention, the thickness of a thin film can be measured by repeating the process described above whenever the thin film is deposited in the chamber 13.

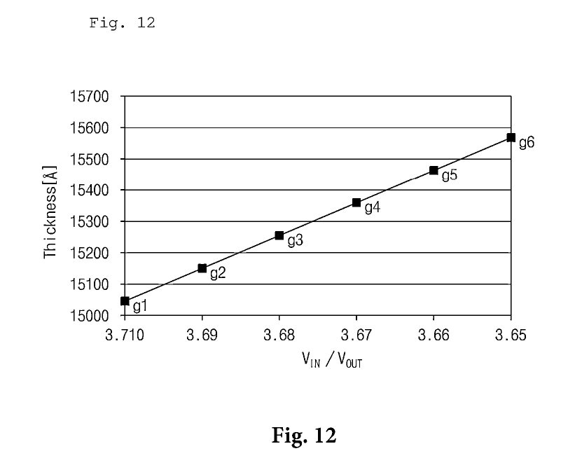

In the present invention, the process of measuring, in real time, the thickness of a thin film for each layer through the RF average value and phase value of RF signals has been described. However, the thickness of the thin film for each layer can also be identified using a gain value rather than a phase value in a secondary measuring process according to the presence of abnormality of the RF average value. An example of the gain value of the thin film for each layer will be illustrated through a graph of FIG. 12.

FIG. 12 is a graph illustrating gain values in the thin film measuring system and the thin film measuring method in accordance with the present invention.

The graph of FIG. 12 illustrates gain values calculated from RF signals detected through the input signal detector 23 and the output signal detector 24 whenever one layer is deposited in a thin film. More specifically, gain values g₁ to g₆ are obtained by measuring gain values according to the thicknesses of the entire thin film whenever the first to sixth layers are sequentially deposited.

Thus, the thin film measuring method further includes a gain value determining step (not shown) of detecting a gain value from the RF signal output from the heater 10 and comparing the detected gain value with a set gain value in the monitoring unit 25, when an abnormality occurs in the RF average value in the RF average value determining step (S13).

Here, the monitoring unit 25 sets a gain value for each thickness increased whenever one layer is deposited, measures a gain value whenever one layer is deposited, and compares the measured gain value with the set gain value, thereby determining the presence of abnormality.

In the gain value determining step, if an abnormality occurs in the gain value, the monitoring unit 25 warns the abnormality of the thickness of the thin film by controlling the alarm unit 26 in the warning step (S16).

Thus, in the present invention, the gain value is measured, in real time, whenever a new layer is deposited, so that it is possible to exactly determine the presence of abnormality of the corresponding layer in the deposition of the new layer.

According to the heater monitoring system of the present invention, as the presence of abnormality of the heater is determined by sensing an RF signal supplied from the RF supply unit to the heat generating coil of the heater, the replacement period of the heater can be managed, thereby improving the productivity of the apparatus.

Further, as the presence of abnormality of the heater is determined by sensing that RF power supplied from the RF supply unit is supplied to the heat generating coil of the heater, the replacement period of the heater can be managed, thereby improving the productivity of the apparatus.

Further, the exchange period of the heater can be determined using measured data, particularly accumulated error data, so that the rate of operation according to the replacement of the heater can be managed in advance, thereby improving the management of manufacturing flow.

Further, in order to exactly detect an inferior product that may be generated because although the thickness of the entire thin film is equal to the set thickness, the thicknesses of layers of the thin film are different, the thickness of a thin film for each layer is measured in real time whenever one layer of the thin film is deposited in the deposition process of the thin film, and the measurement result is fed back, so that exact measurement is possible. Accordingly, it is possible to improve the reliability of products and to determine the presence of abnormality of the heater causing the abnormality of the thickness of the thin film.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A heater monitoring system for a semiconductor thin film deposition apparatus, the heater monitoring system, including:
an RF filter configured to detect that an RF signal applied from an RF supply unit is supplied to a heat generating coil of a heater in a plasma process, wherein the heater is made of any one of Al, AlN and BN, and the RF filter is disposed between a heater power rod and a power supply unit;
a power supply unit configured to apply a driving voltage to the heater through the RF filter; and
a diagnosis unit configured to diagnose the presence of abnormality of the heater by processing the RF signal transmitted from the RF supply unit.

2. The heater monitoring system for a semiconductor thin film deposition apparatus in accordance with claim 1,
wherein said RF filter may include;
an RF signal blocking filter configured to block the supply of the RF signal from the RF supply unit to the power supply unit so that a rating voltage is supplied from the power supply unit to the heater; and
a band pass filter connected to the diagnosis unit to pass band signals of the RF signal supplied to the heat generating coil of the heater and then transmit the band signals to the diagnosis unit.

3. The heater monitoring system for a semiconductor thin film deposition apparatus in accordance with claim 1, wherein said diagnosis unit may include;
a signal processing unit in the form of a comparator, configured to perform an operation of comparing the RF signal passing through a band pass filter with a normal signal or comparing accumulated error data with a set error allowance range;
a determination unit configured to determine the presence of abnormality of the heater by receiving a signal of the signal processing unit; and
an alarm unit configured to notify an abnormality of the heater to the exterior through an audible or visual means when the abnormality occurs in the heater as the determination result of the determination unit.

4. A heater monitoring system for a semiconductor thin film deposition apparatus, the heater monitoring system including:
an induced current sensor unit configured to sense that an induced current generated by an RF signal applied from the RF supply unit is supplied to a heat generating coil of a heater in a plasma process, wherein the heater is made of any one of Al, AlN and BN;
a power supply unit configured to apply a driving voltage to the heater through the RF filter; and
a diagnosis unit configured to include a signal processing unit in the form of a comparator, configured to compare a real-time signal sensed by the induced current sensor unit with a normal signal to diagnose the presence of abnormality of the heater by processing an induced current sensing signal transmitted from the induced current sensor unit, a determination unit configured to determine the presence of abnormality of the heater by receiving a signal of the signal processing unit, and an alarm unit configured to notify an abnormality of the heater to the exterior through an audible or visual means when the abnormality occurs in the heater as the determination result of the determination unit.

5. A heater monitoring system for a semiconductor thin film deposition apparatus, a thin film measuring system, including:
a chamber configured to accommodate a wafer having a thin film deposited thereon;
an RF supply unit configured to supply an RF signal into the chamber;
a heater configured to heat the wafer in the chamber, the heater receiving and outputting RF signals supplied from the RF supply unit; and
a monitoring unit configured to calculate a difference between positive and negative values by detecting, in real time, the RF signal received in the heater in a thin film deposition process, measure a thickness of the thin film by comparing a calculated RF measurement value with an RF measurement value set for each thickness, and determine the presence of abnormality of the wafer and the presence of abnormality of the heater.

6. The heater monitoring system for a semiconductor thin film deposition apparatus in accordance with claim 5, wherein said thin film measuring system may further include;
an input signal detector configured to detect an RF signal supplied from the RF supply unit to the chamber and apply the detected RF signal to the monitoring unit; and
an output signal detector configured to detect an RF signal output from the heater and apply the detected RF signal to the monitoring unit.

7. The heater monitoring system for a semiconductor thin film deposition apparatus in accordance with claim 5, wherein said monitoring unit operates that when an abnormality occurs in the RF measurement value, the monitoring unit may calculate a phase value from the RF signal received in the heater, and compare the calculated phase value with a phase value set for each thickness, thereby determining the presence of abnormality of the deposited thin film.

8. The heater monitoring system for a semiconductor thin film deposition apparatus in accordance with claim 5, wherein said monitoring unit operates that when an abnormality occurs in the RF measurement value, the monitoring unit may calculate a gain value from the RF signal received in the heater, and compare the calculated gain value with a gain value set for each thickness, thereby determining the presence of abnormality of the deposited thin film.

9. A thin film measuring method, including:
an RF transmission/reception step of supplying an RF signal into a chamber, and receiving the RF signal in a heater on which a wafer mounted in the chamber;
a thin film deposition step of depositing a thin film on the wafer through a reaction between gas and the RF signal supplied into the chamber in the RF transmission/reception step;
an RF measurement value determining step of calculating an RF measurement value by operating a difference between positive and negative peak values in the RF signal supplied in the thin film deposition step, and comparing the calculated RF measurement value with an RF measurement value set for each thickness; and
a warning step of warning an abnormality of the thickness of the thin film when the calculated RF measurement value is different from the set RF measurement value in the RF measurement value determining step.

10. The thin film measuring method of claim 9 may further include:
a phase detection step of detecting a phase of the RF signal when the calculated RF measurement value is different from the set RF measurement value in the RF measurement value determining step; and
a phase value change determining step of determining whether the measured phase value is different from a phase value set for each thickness in the phase detection step when it is determined that the measured phase value is different from the set phase value in the phase value change determining step, a warning may be given in the warning step.

11. The thin film measuring method of claim 9 may further include:
a gain value determining step of detecting a gain of the RF signal and determining whether the detected gain value is different from a set gain value, when the calculated RF measurement value is different from the set RF measurement value in the RF measurement value determining step, and when the set gain value is different from the measured gain value in the gain value determining step, a warning may be given in the warning step.
